(19) United States
(12) Patent Application Publication
(10) Pub. No.: US 2009/0213537 A1
(43) Pub. Date: Aug. 27, 2009

(54) Housing for a Computer

(75) Inventor: Klaus Heesen, Leonberg (DE)

Correspondence Address: BANNER & WITCOFF, LTD., 1100 13th STREET, N.W., SUITE 1200, WASHINGTON, DC, 20005-4051, US

(73) Assignee: HUSH TECHNOLOGIES INVESTMENTS LTD, LONDON (GB)

(21) Appl. No.: 11/887,419

(22) PCT Filed: Mar. 30, 2006
(86) PCT No.: PCT/EP2006/002906

§ 371 Date: Mar. 26, 2009

(30) Foreign Application Priority Data
Mar. 30, 2005 (DE) 10 2005 014 534.5

(51) Int. Cl. G06F 1/20; H05K 7/20

(52) U.S. Cl. 361/679.47; 361/679.54; 361/679.52

(57) ABSTRACT

A housing for a computer or multi-media equipment or the like includes at least one heat-generating component. The housing may have a respective cooling body on opposing walls and a heat conduction conduit that is thermally coupled to the heat-generating component. The heat conduction conduit can run along both opposing walls and is thermally coupled to the cooling bodies, whereby heat from the heat-generating component can be dissipated from the housing via the heat conduction conduit and the cooling bodies. By running the heat conduction conduit along opposing walls, heat may be transferred in a rapid, uniform manner to the entire surface of the cooling bodies that are contained in the walls.

The present invention relates to a housing for a computer or multi-media device or similar.

### PRIOR ART

Computers contain heat-generating components such as, for example, processors and power supplies. As a result of the increasing performance and power consumption, measures for cooling these components are required. For example, it is known to use fans.

A computer housing which manages without using fans is known from WO 02/075510. For this purpose heat sinks with cooling fins are integrated in the side walls of the housing and are thermally coupled to heat-generating components, in particular a processor. The thermal coupling is achieved by means of a so-called heat pipe comprising a first body attached to a processor and a second body attached to the heat sink integrated in one of the two side walls. A coolant flows via a pipe between the two bodies to transport heat from the first body to the second body and thus to the heat sink.

The purpose of all cooling devices for computers should be to generate the highest possible heat output power. When using heat sinks however, there is the problem of distributing the heat to be dissipated sufficiently rapidly to the largest possible surface of the heat sink.

It is the object of the present invention to address this problem. This object is achieved by the invention specified in claim 1. Advantageous embodiments can be deduced from the dependent claims.

### SUMMARY OF THE INVENTION

According to the invention, a housing is provided for a computer or multi-media device or similar, comprising at least one heat-generating component, wherein the housing is provided with a heat sink on opposing walls, respectively, and a heat conduit for thermal coupling to the heat-generating component, the heat conduit extending along both opposing walls and is thermally coupled to the heat sinks whereby heat from the heat-generating component can be dissipated from the housing via the heat conduit and the heat sinks.

By laying the heat conduit along opposing walls, heat can be transferred uniformly and rapidly over the entire surface of the heat sinks contained in the walls.

This avoids the disadvantages of a conventional punctiform thermal coupling of a heat-generating component to a heat sink. These consist in that heat is stored rather than dissipated above a certain thickness of heat sink whereas below a certain thickness approximately no further distribution of heat takes place.

In contrast, the housing according to the invention ensures that heat is dissipated over the entire heat sink surfaces of the two opposing walls. So-called potentially unpleasant “hot spots” on the outer sides of the heat sinks are avoided.

The opposing walls are preferably formed by the opposing side walls of the housing. Alternatively however, the heat conduits can extend along the upper and lower side (i.e., the ceiling and floor wall) or the front and rear wall of the housing. The heat conduits can also extend along combinations of walls of the housing, e.g. along two opposing walls and at least one wall of the housing which connects the two opposing walls, in particular along both side walls and one or more of the ceiling, floor, front and rear walls. The cooling capacity can thus be adapted to the installation of the housing and the one or more heat-generating components provided therein.

According to an advantageous embodiment, the heat sinks and the heat conduit each extend substantially over the entire length of both the opposing walls. This configuration results in a particularly efficient and uniform removal of heat.

According to another embodiment, the heat conduit extends along both side walls and in between along the front and/or rear wall of the housing. According to this embodiment, heat is dissipated not only via the side walls but also via the front and/or rear wall of the housing.

In a preferred embodiment, the heat-generating component is thermally coupled to the heat conduit in the region between the opposing walls. The coupling is preferably provided at the centre between the opposing walls. This results in a particularly uniform heat distribution on two opposing walls.

In an alternative embodiment, the heat-generating component is thermally coupled to the heat conduit at one of the walls in the area of the heat sink. This embodiment has the advantage that the coupling takes place in the immediate vicinity of one of the heat sinks.

In one embodiment of the invention, at least one heat pipe is associated with the heat-generating component, by which means the heat-generating component is coupled to the heat conduit. As a result of this indirect thermal coupling, the structure of the housing can be simplified.

The heat pipe associated with the heat-generating component is preferably mechanically thermally coupled to the heat conduit. This contributes to a simple and robust structure of the housing. In particular, the heat pipe and the heat conduit can be fixed to the inside of the housing by means of a heat-conducting holder. For optimum thermal coupling the heat conduit and the heat pipe extend inside the holder parallel and at a short distance from one another.

It is advantageous if the heat pipe and the heat conduit extend inside recesses in the holder and the inside of the housing where the recesses extend parallel and at a short distance from one another. The thermal coupling between the heat pipe and the heat conduit is thereby further improved.

In one embodiment, the holder is formed by an aluminum or copper block. These materials offer the advantages of low weight and good thermal conductivity.

In a preferred embodiment, a plurality of heat conduits is provided for thermal coupling to the heat-generating component, wherein each of the heat conduits extends along both opposing walls and is thermally coupled to the heat sinks. This embodiment further improves the cooling efficiency.

The heat removal is particularly efficient if each of the heat conduits extends substantially over the total length of the two opposing walls.

Preferably each of the heat conduits extends along both the side walls and in between along the front and/or rear wall of the housing. This also ensures heat removal via the front and/or rear wall.

The heat conduits advantageously extend parallel to one another. As a result, heat exchange can take place between the individual heat conduits amongst one another, whereby the heat removal from the housing is distributed more uniformly.

In one embodiment, the one or a plurality of heat conduits are formed by so-called heat-pipes, in particular by liquid cooling pipes. Such liquid cooling pipes have proved to be particularly efficient.

The heat sinks are preferably formed as integral components of the opposing walls. Since the heat conduit extends along the opposing walls, this gives optimum thermal coupling between the heat conduction pipe and the heat sink.

The heat sinks preferably each comprise a plurality of cooling fins to improve the cooling performance.

The one or the plurality of heat conduction conduits can preferably extend in recesses in the opposing walls to further improve the thermal coupling between the heat conduit or conduits and the opposing walls.

Overall it was established that as a result of the transfer of heat, for example, along the heat sinks of the two side walls of the housing, an increased heat removal capacity of more than 20% is achieved compared with quasi-punctiform coupling to one of the side walls. Over its total length (390 mm according to a tested embodiment) along the side walls, the heat sink exhibited maximum temperature differences of 2 degree centigrade (i.e. about 0.5 degree centigrade per 100 mm). The heat difference between the two side walls was less than 2.5 degrees centigrade.

### BRIEF DESCRIPTION OF THE DRAWINGS

The invention is now explained using exemplary embodiments with reference to the drawings. In the figures:

FIG. 1 is a schematic plan view of a computer housing according to one embodiment of the invention with the cover plate removed;

FIG. 2 is a schematic front view of a computer housing according to one embodiment of the invention with the front plate removed; and

FIG. 3 is a schematic perspective view of a computer housing according to one embodiment of the invention with the front and cover plate removed.

### DETAILED DESCRIPTION

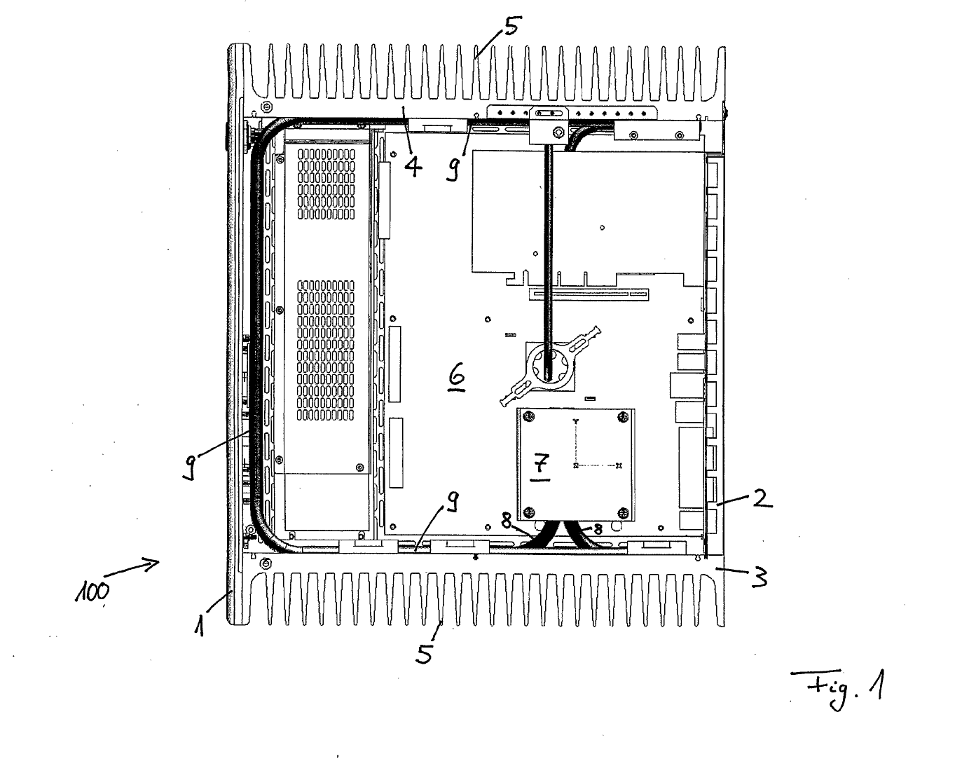

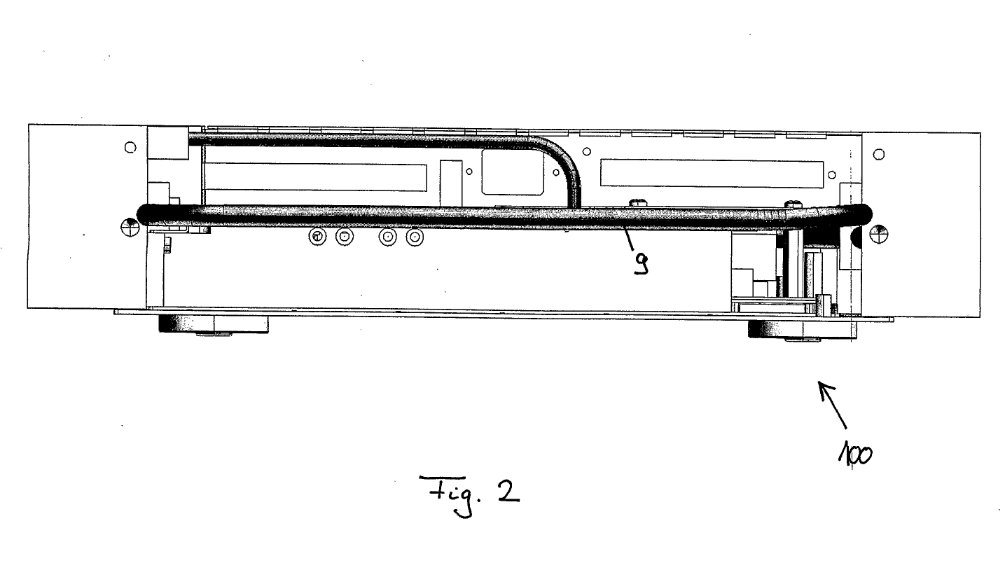

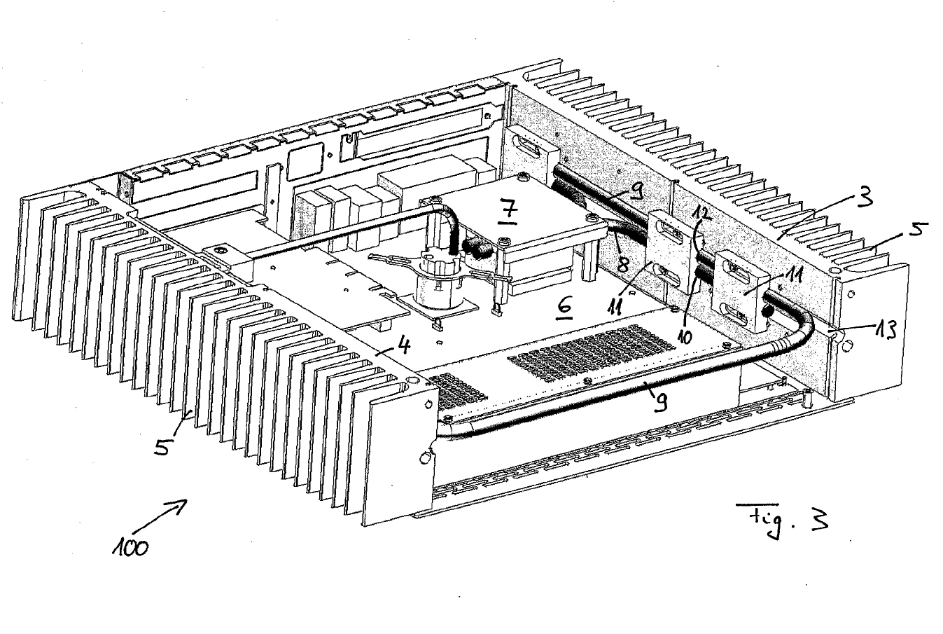

FIGS. 1 to 3 illustrate schematically an opened computer housing 100 according to one embodiment of the invention, where FIG. 1 is a plan view of the housing 100 with the cover plate removed, FIG. 2 is a front view with the front plate removed and FIG. 3 is a perspective view likewise with the cover plate removed. In all three figures, the same reference numerals are used for elements which correspond to one another.

The computer housing 100 has a front wall 1, a rear wall 2 and side walls 3 and 4 located opposite to one another. The side walls 4 comprise a plurality of cooling fins 5 and thus each form a heat sink for removing heat from the housing 100. The cooling fins extend perpendicularly to the longitudinal extension of the side walls 3, 4 and are uniformly spaced apart. The surface of the cooling fins can be corrugated for better heat removal.

The interior of the computer housing 100 contains a motherboard 6 on which a heat-generating element 7 is located. The heat-generating element 7 comprises, for example, a main processor (CPU) or a graphics processor (GPU).

The heat-generating element 7 is thermally coupled to so-called heat pipes 8. The heat pipes 8 are for their part thermally coupled to the side wall 3 and a heat conduit 9. In the illustrated embodiment, the heat pipes 8 are thermally coupled to the side wall 3 by the ends of the heat pipes 8 facing away from the heat-generating element 7 extending in first recesses 10 which extend on the inner side of the side wall 3 and in fixing blocks 11. The fixing blocks 11 are used to fix the heat pipes 8 to the inside of the side wall 3. The heat conduit 9 extends parallel to the heat pipes 8 in second recesses 12 likewise provided on the inside of the side wall 3 and the fixing blocks 11.

The fixing blocks 11 consist of a material having sufficiently high thermal conductivity such as, for example, aluminum or copper. As a result and due to the sufficient proximity of the heat pipes 8 to the heat conduit 9 and their parallel arrangement in sections, good heat transfer takes place from the heat pipes 8 (and thus from the heat-generating element 7) to the heat conduit 9.

The heat conduit 9 extends substantially along the entire longitudinal extension of the side walls 2 and 3 and the front wall 1. As can be seen in the plan view from FIG. 1, the heat conduit 9 thus forms a U which extends along three of the four outer walls of the housing 100. As has been described with reference to the side wall 3, depending on the embodiment, the heat conduit 9 can extend in corresponding recesses 13 on the inner sides at least of the side walls 2 and 3, thereby providing optimum thermal coupling to the outside.

It should be noted that the exemplary embodiment described is merely of an exemplary nature and the invention comprises modifications within the scope of protection defined by the protective claims, For example, the housing is not only suitable for computers and multi-media devices but also for audio/video devices (e.g. amplifiers, DVD plays, CD players etc.). In addition, the heat-generating component is not restricted to CPUs and GPUs but also comprises other heat-generating components such as are found in computers, multi-media devices, audio and video devices etc. such as for example voltage converters, power supplies, hard disks etc. The heat conduit can also be thermally coupled to a plurality of such heat-generating components.

1. A housing for a computer or multi-media device or similar, comprising at least one heat-generating component, wherein the housing is provided with a heat sink on opposing walls, respectively, and a heat conduit for thermal coupling to the heat-generating component, the heat conduit extending along both opposing walls and is thermally coupled to the heat sinks whereby heat from the heat-generating component can be dissipated from the housing via the heat conduit and the heat sinks.

2. The housing according to claim 1, wherein the opposing walls are formed by the opposing side walls, the combination of floor and ceiling walls and/or the combination of front and rear wall of the housing.

3. The housing according to claim 1, wherein the heat sinks and the heat conduit each extend substantially over the entire length of the opposing walls.

4. The housing according to claim 1, wherein the heat conduit extends along both opposing walls and at least one wall of the housing which connects the two opposing walls.

5. The housing according to claim 4, wherein the heat conduit extends along both side walls and in between along the front and/or rear wall of the housing.

6. The housing according to claim 5, wherein the heat-generating component is thermally coupled to the heat conduit in the region between the opposing walls, preferably at the centre between the opposing walls.

7. The housing according to claim 1, wherein the heat-generating component is thermally coupled to the heat conduit at one of the walls in the area of the heat sink.

8. The housing according to claim 1, wherein at least one heat pipe is associated with the heat-generating component, by which means the heat-generating component is coupled to the heat conduit.

9. The housing according to claim 1, wherein the heat pipe associated with the heat-generating component is mechanically thermally coupled to the heat conduit.

10. The housing according to claim 9, wherein the heat pipe and the heat conduit are fixed to the inside of the housing by means of a heat-conducting holder.

11. The housing according to claim 10, wherein the heat pipe and the heat conduit extend in the holder parallel and at a short distance from one another.

12. The housing according to claim 11, wherein the heat pipe and the heat conduit extend inside recesses in the holder and the inside of the housing and the recesses extend parallel and at a short distance from one another.

13. The housing according to claim 10, wherein the holder is formed by an aluminum or copper block.

14. The housing according to claim 1, comprising a plurality of heat conduits for thermal coupling to the heat-generating component, wherein each of the heat conduits extends along both opposing walls and is thermally coupled to the heat sinks.

15. The housing according to claim 14, wherein each of the heat conduits extends substantially over the total length of the two opposing walls.

16. The housing according to claim 14, wherein each of the heat conduits extends along the opposing side walls and in between along the front of rear wall of the housing.

17. The housing according to claim 14, wherein the heat conduits extend parallel to one another.

18. The housing according to claim 1, wherein one or a plurality of heat conduits are formed by liquid cooling pipes.

19. The housing according to claim 1, wherein the heat sinks are formed as integral components of the opposing walls.

20. The housing according to claim 19, wherein the heat sinks each comprise a plurality of cooling fins.

21. The housing according to claim 1, wherein the one or the plurality of heat conduits extend in recesses in the opposing walls.

22. A computer comprising at least one heat-generating component and housing according to claim 1.
